(19) United States
(12) Patent Application Publication
(10) Pub. No.: US 2009/0231803 A1
(43) Pub. Date: Sep. 17, 2009

(54) Casing used for Electronic Device and Server for Computing

(76) Inventor: Ting-Yi Chang, Sijhih City (TW)

Correspondence Address: KAMRATH & ASSOCIATES P.A., 4825 OLSON MEMORIAL HIGHWAY, SUITE 245, GOLDEN VALLEY, MN, 55422, US

(21) Appl. No.: 12/037,133

(22) Filed: Feb. 26, 2008

(51) Int. Cl. G06F 1/20; H05K 5/00; H05K 7/20; A47B 81/00

(52) U.S. Cl. 361/679.47; 361/688; 312/223.2; 361/679.58; 361/679.54; 312/223.1

(57) ABSTRACT

The present invention provides a casing used for electronic device and server for computing, wherein the server including a casing and a circuit board, and the casing including a casing body and a carrier mechanism. The casing body has an internal space, and the carrier mechanism including a carrier unit and a fastening unit, wherein the carrier unit is disposed in the internal space and it carries the circuit board. The fastening unit is disposed on the terminal of the carrier unit, wherein the fastening unit has a handle. One terminal of the handle is pivoted on the carrier unit, and the other terminal has a fastening element, which is for the use of fastening on the casing body. The present invention can shorten the time spending on replacing the electronic components by using the casing used for electronic device so as to facilitate the users.

### BACKGROUND OF THE INVENTION

1. Field of the Invention

The present invention relates to a casing. More particularly, the present invention relates to a casing used for electronic device and a server for computing.

2. Description of the Prior Art

Due to the improvement of information technology and the popularity of internet, the application of servers is more and more common. At present, the structure of a server commonly includes pluralities of circuit boards installed in a casing, wherein several kinds of electronic components are installed on the circuit boards.

However, it is unavoidable that some electronic components might break down or need upgrade after a period of time of use. When this happens, the users usually have to take apart the casing to replace the electronic components. At present, the procedure for replacing the electronic components commonly includes: taking apart the casing, replacing the broken or upgradeable electronic components and reassembling the casing. However, the replacement procedure costs much time, resulting in the inconvenience for the users.

It would, therefore, be desirable to redesign the casing which makes it easier and faster to replace the electronic components.

### SUMMARY OF THE INVENTION

The present invention provides a casing used for electronic device, in which the casing allows users to replace the electronic components more easily and faster.

To achieve the foregoing and other objects, a casing used for electronic device is provided, in which the casing includes a casing body and a carrier mechanism. The casing body has an internal space, and the carrier mechanism includes a carrier unit and a fastening unit. The carrier unit is disposed in the internal space, and it is adapted to carry a circuit board. The fastening unit is disposed at the terminal of the carrier unit, in which a handle is installed on the fastening unit. One terminal of the handle is pivoted on the fastening unit, and the other terminal of the handle has a fastening element which is for the use of fastening on the casing body.

In the present casing used for electronic device, there are two said handles. One of the handles is pivoted on one side of the fastening unit, and the other handle is pivoted on the opposite side of the fastening unit.

In the present casing used for electronic device, the handle includes a transverse side plate and a longitudinal side plate, which are welded together. The transverse side plate is pivoted on the top surface of the fastening unit, and the fastening element is disposed on the longitudinal side plate.

In the present casing used for electronic device, at least a heat sink is installed inside the fastening unit.

In the present casing used for electronic device, the fastening element is a screw.

To achieve the foregoing and other objects, a server for computing is provided, in which the server includes a casing and a circuit board. The casing includes a casing body and a carrier mechanism. The casing body has an internal space, and the carrier mechanism includes a carrier unit and a fastening unit. The carrier unit is disposed in the internal space and carries the circuit board. The fastening unit is disposed at the terminal of the carrier unit, in which a handle is installed on the fastening unit. One terminal of the handle is pivoted on the fastening unit, and the other terminal of the handle has a fastening element which is for the use of fastening on the casing body.

In the present server, there are two said handles. One of the handles is pivoted on one side of the fastening unit, and the other handle is pivoted on the opposite side of the fastening unit.

In the present server, the handle includes a transverse side plate and a longitudinal side plate, which are welded together. The transverse side plate is pivoted on the top surface of the fastening unit, and the fastening element is disposed on the longitudinal side plate.

In the present server, at least a heat sink is installed inside the fastening unit.

In the present server, there is an air guide hood, which corresponds to the heat sink, installed on the circuit board.

In the present server, the fastening element is a screw.

In summary, the present invention can shorten the time spending on replacing the electronic components by using the casing used for electronic device so as to facilitate the users. Moreover, when manufacturing the servers, the manufacturer can save the cost by using the present casing.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is an explosive view of a computing server of the first embodiment.

FIG. 2 is an assembly drawing of a server of the first embodiment.

FIG. 3A and FIG. 3B are the process of taking apart the carrier mechanism.

### DESCRIPTION OF THE PREFERRED EMBODIMENTS

Reference will now be made in detail to the preferred embodiments of the present invention, examples of which are illustrated in the accompanying drawings. Wherever possible, the same reference numbers are used in the drawings and the description to refer to the same or like parts.

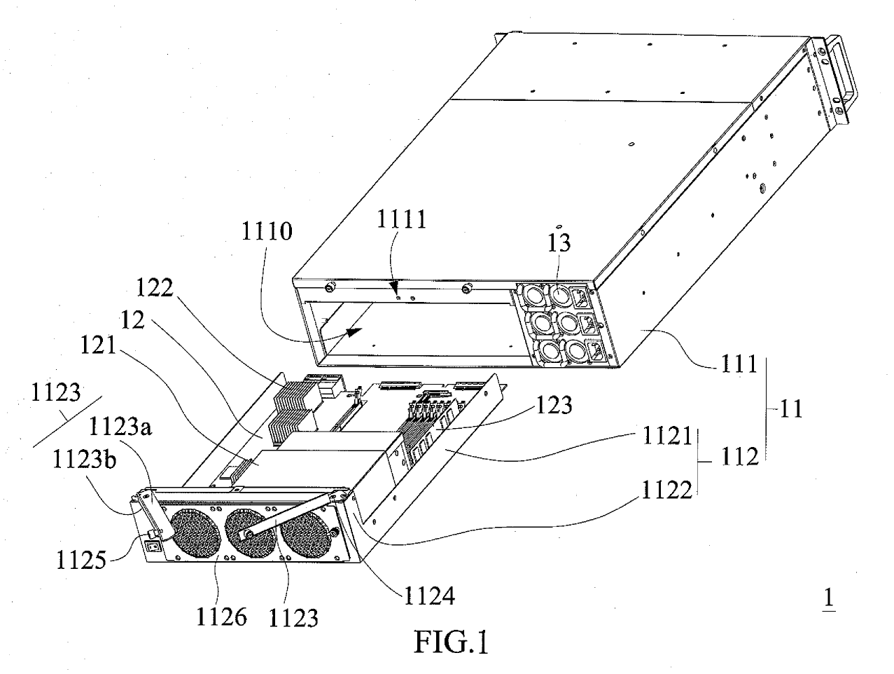

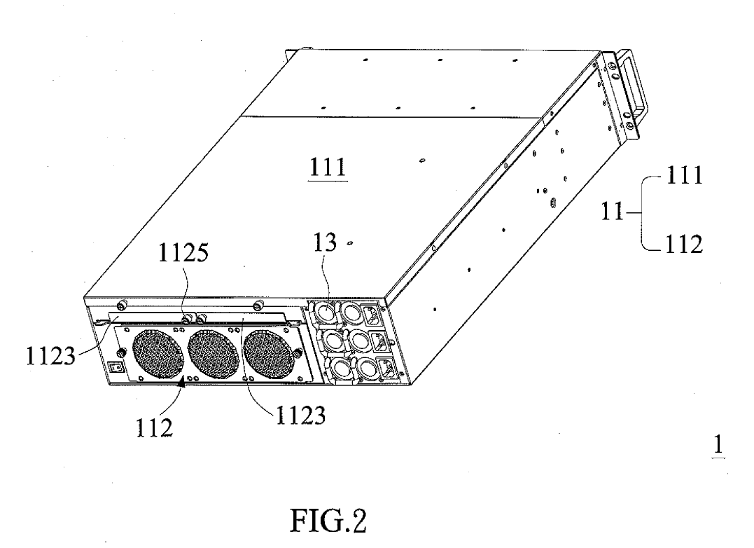

Please refer to FIG. 1 and FIG. 2 for an explosive view and an assembly drawing of a server of the first embodiment respectively. There is a server 1, including a casing 11 and a power supply unit 13 which provides the server 1 with the power needed, wherein the casing 11 includes a casing body 111 and a carrier mechanism 112. The casing body 111 has an internal space 1110, and the carrier mechanism 112 is disposed in the internal space 1110. Moreover, the carrier mechanism 112 includes a carrier unit 1121 and a fastening unit 1122, which is disposed at the terminal of the carrier unit 1121. A circuit board 12 is disposed on the carrier unit 1121, wherein pluralities of electronic components are installed on the circuit board 12, such as a memory 123. There are heat sinks 122 disposed on some of the electronic components to increase the cooling effect. Besides, on both sides of the top surface of the fastening unit 1122 are pivoted two handles 1123 fastened by rotary screws 1124 respectively, wherein each one of the handles 1123 includes a transverse side plate 1123a and a longitudinal side plate 1123b. The transverse side plate 1123a is pivoted on the top surface of the fastening unit 1122, and the longitudinal side plate 1123b has a screw 1125, which can be locked with the pinhole 1111 of the casing body 111.

Please refer to FIG. 1 again. A fan assembly 1126 is disposed inside the fastening unit 1122, wherein the fan assembly 1126 includes three fans, which are drawing fans, to diffuse the heat inside the server 1. In addition, an air guide hood 121 is installed on the circuit board 12, wherein the air guide hood 121 and two fans of the fan assembly 1126 are in the corresponding positions. That is to say, the air guide hood 121 is disposed in the vent of the two fans.

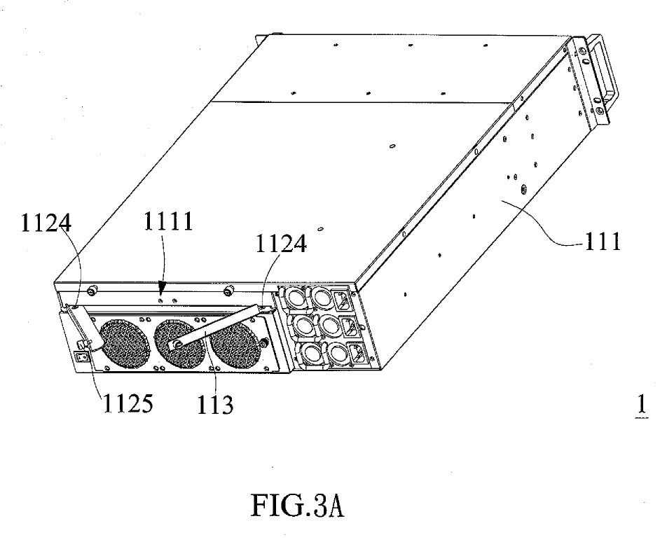

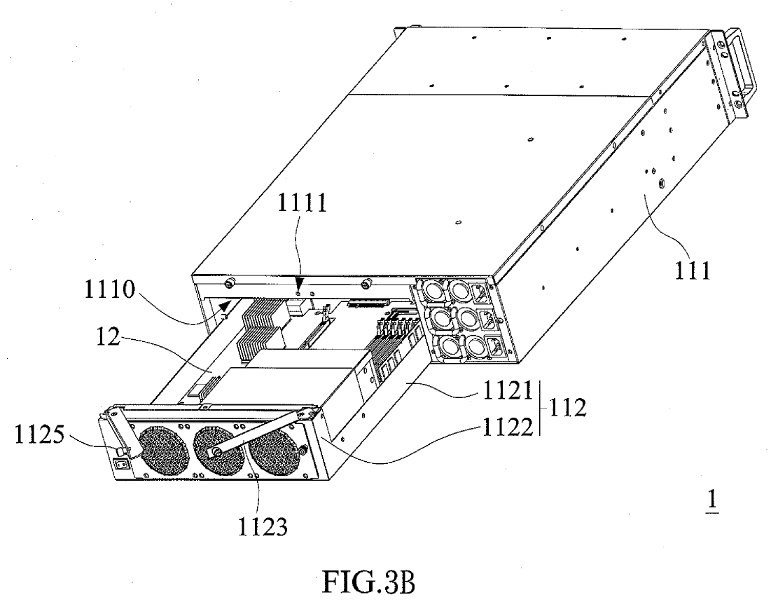

What follows is the process of how the carrier mechanism 112 is taken apart from the casing body 111. Please refer to FIG. 2 and FIG. 3A. First, the users loosen the screws 1125 to separate the screws 1125 and the pinholes 1111 of the casing body 111. Then, the users pivot the rotary screws 1124 to turn the handles 1123 for some angles. Next, please refer to FIG. 3B. The users can hold the handles 1123 and slide the whole carrier mechanism 112 backward, so as to pull the carrier unit 1121 of the carrier mechanism 112 out of the internal space 1110 of the casing body 111. Afterward, the users can replace the electronic components on the circuit board 12. After the replacement is done, the users can push the carrier unit 1121 back into the internal space 1110 and then lock the screws 1125 to the pinholes 1111 of the casing body 111.

Several points for attention, there are two said handles 1123 in the present embodiment, yet those skilled in the art can also install only one said handle 1123 depending on their needs. Moreover, there is one said screw 1125 installed on each one of the handles 1123 of the embodiment, yet the number of the screw 1125 is not a limitation of the invention. Those skilled in the art can install more than one said screw 1125 on each one of the handles 1123. Besides the fastening unit 1125, those skilled in the art can still lock the handles 1123 to the casing body 111 by means of other fastening elements (such as a buckle unit).

In summary, the present invention can shorten the time spending on replacing the electronic components by using the casing used for electronic device so as to facilitate the users. Moreover, when manufacturing the servers, the manufacturer can save the cost by using the present casing.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

I claim:

1. A casing used for electronic device, comprising:
a casing body, having an internal space; and
a carrier mechanism, comprising a carrier unit and a fastening unit, wherein the carrier unit, which is adapted to carry a circuit board, is disposed in the internal space, and the fastening unit is disposed at the terminal of the carrier unit, wherein a handle is installed on the fastening unit, wherein one terminal of the handle is pivoted on the fastening unit, and the other terminal of the handle has a fastening element which is for the use of fastening on the casing body.

2. The casing used for electronic device according to claim 1, wherein there are two said handles, one of the handles is pivoted on one side of the fastening unit, and the other handle is pivoted on the opposite side of the fastening unit.

3. The casing used for electronic device according to claim 1, wherein the handle comprises a transverse side plate and a longitudinal side plate, wherein the transverse side plate is pivoted on the top surface of the fastening unit, and the fastening element is disposed on the longitudinal side plate.

4. The casing used for electronic device according to claim 1, wherein at least a heat sink is installed inside the fastening unit.

5. The casing used for electronic device according to claim 1, wherein the fastening element is a screw.

6. A server for computing, comprising:
a circuit board; and
a casing, comprising:
a casing body, having an internal space; and
a carrier mechanism, comprising a carrier unit and a fastening unit, wherein the carrier unit, which is adapted to carry a circuit board, is disposed in the internal space, and the fastening unit is disposed at the terminal of the carrier unit, wherein a handle is installed on the fastening unit, wherein one terminal of the handle is pivoted on the fastening unit, and the other terminal of the handle has a fastening element which is for the use of fastening on the casing body.

7. The server for computing according to claim 6, wherein there are two said handles, one of the handles is pivoted on one side of the fastening unit, and the other handle is pivoted on the opposite side of the fastening unit.

8. The server for computing according to claim 6, wherein the handle comprises a transverse side plate and a longitudinal side plate, wherein the transverse side plate is pivoted on the top surface of the fastening unit, and the fastening element is disposed on the longitudinal side plate.

9. The server for computing according to claim 6, wherein at least a heat sink is installed inside the fastening unit.

10. The server for computing according to claim 9, wherein an air guide hood is installed on the circuit board, and the air guide hood as well as the heat sink are in the corresponding position.

11. The server for computing according to claim 6, wherein the fastening element is a screw.
